(19) United States
(12) Patent Application Publication
(10) Pub. No.: US 2013/0127552 A1
(43) Pub. Date: May 23, 2013

(54) Ovenized System Containing Micro-Electromechanical Resonator

(71) Applicants: Jonathan Borremans, Lier (BE); Michiel Antonius Petrus Pertijs, Delft (NL)

(72) Inventors: Jonathan Borremans, Lier (BE); Michiel Antonius Petrus Pertijs, Delft (NL)

(73) Assignee: IMEC, Leuven (BE)

(21) Appl. No.: 13/300,950

(22) Filed: Nov. 21, 2011

(30) Foreign Application Priority Data
Nov. 17, 2011 (EP) 11189555.3

(51) Int. Cl. H03L 1/02

(52) U.S. Cl. 331/70

(57) ABSTRACT

Disclosed an electronic device comprising an ovenized system containing a micro-electromechanical (MEM) resonator and a method for controlling such an MEM resonator. In one embodiment, the MEM resonator comprises a resonator body suspended above a substrate by means of at least a first and a second mechanical support forming a first and a second heating resistance, respectively, configured to heat the resonator body through Joules heating, biasing means configured to apply a bias voltage to the resonator body to enable vibration at a predetermined operating frequency, a temperature control system configured to control the temperature of the micro-electromechanical resonator, and an internal voltage monitoring system configured to monitor a voltage level of the resonator body.

### CROSS-REFERENCE TO RELATED APPLICATIONS

This application claims priority to European Patent Application Serial No. 11189555.3 filed Nov. 17, 2011, the contents of which are hereby incorporated by reference.

BACKGROUND ART

A temperature control system for a MEMS oscillator is known from James C. Salvia et al., “Real-Time Temperature Compensation of MEMS Oscillators Using an Integrated Micro-Oven and a Phase-Locked Loop”, Journal Of Microelectromechanical Systems, Vol. 19, No. 1, February 2010. The circuit is shown in FIG. 1. Heating happens through mechanical supports R_{A} and R_{B}. A sensing point of the internal voltage of the MEMS oscillator is made to use a feedback loop to keep the internal voltage stable to a wanted value, with minor impact on the heating, through amplifier OA1 and OA2. For mechanical symmetry, two sensing points R_{C} and R_{D} are made, since the sensing resistors are two additional support beams on the MEMS resonator. This circuit has the disadvantage that the addition of the mechanical connections to the MEMS device impacts the mechanical performance and adds paths for heat loss, which increases the power consumption.

Another method, Krishnakumar Sundaresan et al., “A Low Phase Noise 100 MHz Silicon BAW Reference Oscillator”, IEEE 2006 Custom Intergrated Circuits Conference (CICC), does not sense the internal voltage of the MEMS device, but uses a squaring function generator to compensate the theoretical bias voltage increase with heating power. This can be inaccurate as the actual voltage is not sensed. Further, the approach includes complicated squaring circuitry overhead, and the block consumes 170 mW.

### SUMMARY

The present disclosure relates to an electronic device comprising an ovenized system containing a micro-electromechanical (MEM) resonator, and a temperature control system for controlling the temperature of the micro-electromechanical resonator.

The present disclosure further relates to a method for controlling a micro-electromechanical resonator in an ovenized system.

The disclosed devices and methods may allow the internal voltage of a micro-electromechanical resonator in an ovenized system to be accurately monitored, such that an impact on mechanical performance and heat loss can be avoided.

Disclosed is an electronic device comprising an ovenized system containing a micro-electromechanical (MEM) resonator, the resonator comprising a resonator body suspended above a substrate by means of at least a first and a second mechanical support forming a first and a second heating resistance for heating the resonator body through Joules heating, and a biasing means (e.g., comprising one or more electrodes) provided for applying a bias voltage to the resonator body to enable vibration at a predetermined operating frequency.

Also disclosed is a temperature control system configured to control the temperature of the micro-electromechanical resonator. By means of this temperature control system, the variation of the parameters of the MEM resonator over temperature can be counteracted by stabilizing the temperature of the MEM resonator. This is achieved in a power efficient way by the oven-controlled setup. The MEM resonator is warmed up in the micro-oven to a temperature above the ambient temperature, the temperature of the MEM resonator is monitored, and kept fixed, i.e. within a narrow, predetermined range of e.g. 0.10° C., which can for example be monitored by means of a temperature sensing means provided on or in the vicinity of the resonator body. Hence the MEM resonator is always at substantially the same temperature, and its parameters can be kept stable.

In some embodiments, the temperature control system may include current driving means (e.g. sourcing and/or sinking current source, voltage source, tunable resistance(s), or other) provided for driving an electrical current (e.g. DC) through the first and second heating resistances, and control means, connected to the current driving means and provided for controlling the current driving means.

The current driven through the first and second heating resistances/mechanical supports results in respective voltage drops over the mechanical supports. Hence, the internal voltage level of the resonator body may vary, which affects the bias voltage, i.e. the voltage difference between the resonator body and the biasing means (e.g. electrode(s)). In general, the resonator bias voltage may change as a function of heating power. Typically power is a quadratic function of applied current, while bias voltage is a linear function of applied current. In order to be able to compensate for this variation, the device of the disclosure further comprises an internal voltage monitoring system. In some embodiments, the internal voltage monitoring system may comprise a replica circuit comprising a third and a fourth resistance in parallel over the first and second heating resistances and replicating the resistance ratio of the first and second heating resistances, so that an intermediate connection between the third and fourth resistances replicates the voltage level of the resonator body, and a compensation means connected to the intermediate connection between the third and fourth resistances and provided for compensating for deviations of the replicated voltage level at the intermediate connection from a predetermined voltage level.

With the internal voltage monitoring system of the device of the disclosure, the internal voltage of the resonator body can be monitored without the addition of any sensing nodes or connections to the resonator body. As a result, impact on the mechanical operation can be avoided and also the creation of additional paths for heat loss can be avoided.

The internal voltage monitoring system of the device of the disclosure senses an actual voltage level, which is a replica of the internal voltage level of the resonator body. As a result, a higher accuracy can be achieved with respect to a monitoring system on the basis of theoretical calculations.

In embodiments according to the disclosure, the compensation can be on the current which is driven through the first and second heating resistances. This can for example be achieved in that the compensation means comprises an additional current driving means (e.g. sourcing and/or sinking current source, voltage source, tunable resistance(s), or other), parallel over the current driving means of the temperature control system. Otherwise, this can for example be achieved by providing a feedback of the voltage level on the intermediate connection to the control means of the temperature control system.

For controlling the additional current driving means, the compensation means can comprise an additional control means, which is connected to an output of a comparator, a difference amplifier (e.g. an operational amplifier or an operational transconductance amplifier) or other evaluation block for comparing the voltage on the intermediate connection with a reference for the predetermined voltage level.

In embodiments according to the disclosure, the compensation can also be on the bias voltage which is applied to the resonator body. This can be achieved by adjusting the voltage supplied to the biasing means by the same amount as the deviation which is sensed by the compensation means. So in this case, the compensation means provide feedback to the biasing means.

In some embodiments, the compensation on the currents could be performed, since the electrostatic actuator voltage supplied to the biasing means is typically a high voltage (e.g. at least 50 V, high with respect to solid-state technologies), which can be difficult to manipulate. However, the compensation on the bias voltage is to be additionally considered within the scope of the present disclosure.

In embodiments according to the disclosure, the third and fourth resistances can have very high resistance values with respect to the first and second resistances, e.g. at least 10 times higher, for instance at least 100 times higher, so that the third and fourth resistances conduct very little current and have very little impact on the current driven through the first and second resistances.

In embodiments according to the disclosure, the first and second mechanical supports can be part of a clamped-clamped beam, the resonator body being connected to the first and second mechanical supports by means of a connection part. The first and second mechanical supports can however also be individual support beams on which the resonator body is suspended. In this embodiment, the clamped-clamped beam with Joule heating, replica circuit, etc., is provided on both sides of the resonator body for symmetry purposes.

In embodiments according to the disclosure, the first and second heating resistances have substantially the same resistance values. This is however not essential: the heating resistances can also have different values, resulting from for example different lengths of the mechanical supports.

### BRIEF DESCRIPTION OF THE DRAWINGS

FIG. 1 shows a typical ovenized system containing a pair of MEM oscillators and a monitoring circuit for monitoring the internal voltage of the oscillators.

FIG. 2 compares the temperature dependency of parameters of MEMS resonators to those of quartz resonators, according to an example embodiment.

FIG. 3 shows a schematic general overview of an electronic device, according to an example embodiment.

FIG. 4 shows a perspective view of a MEM resonator which can be used in electronic devices, according to an example embodiment.

FIG. 5 shows a top view of a MEM resonator which can be used in electronic devices according to the disclosure.

FIG. 6 shows a first embodiment of a control circuit for controlling a MEM resonator, according to an example embodiment.

FIG. 7 shows a second embodiment of a control circuit for controlling a MEM resonator, according to an example embodiment.

FIG. 8 shows a third embodiment of a control circuit for controlling a MEM resonator, according to an example embodiment.

FIG. 9 shows a fourth embodiment of a control circuit for controlling a MEM resonator, according to an example embodiment.

FIG. 10 shows a possible implementation for the control circuit of FIG. 9, according to an example embodiment.

FIG. 11 shows a measurement example achieved by means of the implementation of FIG. 10, according to an example embodiment.

FIG. 12 shows a control circuit for controlling a MEM resonator, according to an example embodiment.

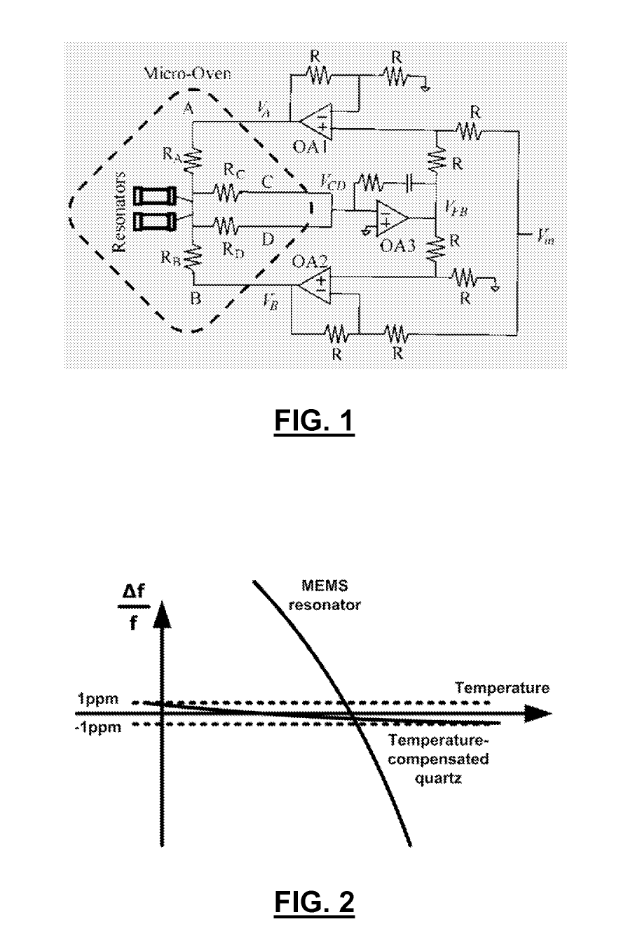

### DETAILED DESCRIPTION

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the disclosure described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present disclosure, the only relevant components of the device are A and B.

As used herein, the term resonator encompasses all structures having or capable of having a desired mechanical or electro-mechanical vibration. In the example that follows, a bar resonator is used. The disclosure is however not limited to resonant beams having rectangular cross sections. Other shapes (e.g. square, circular, parallelepiped, cube, etc.) are also possible within the scope of the disclosure.

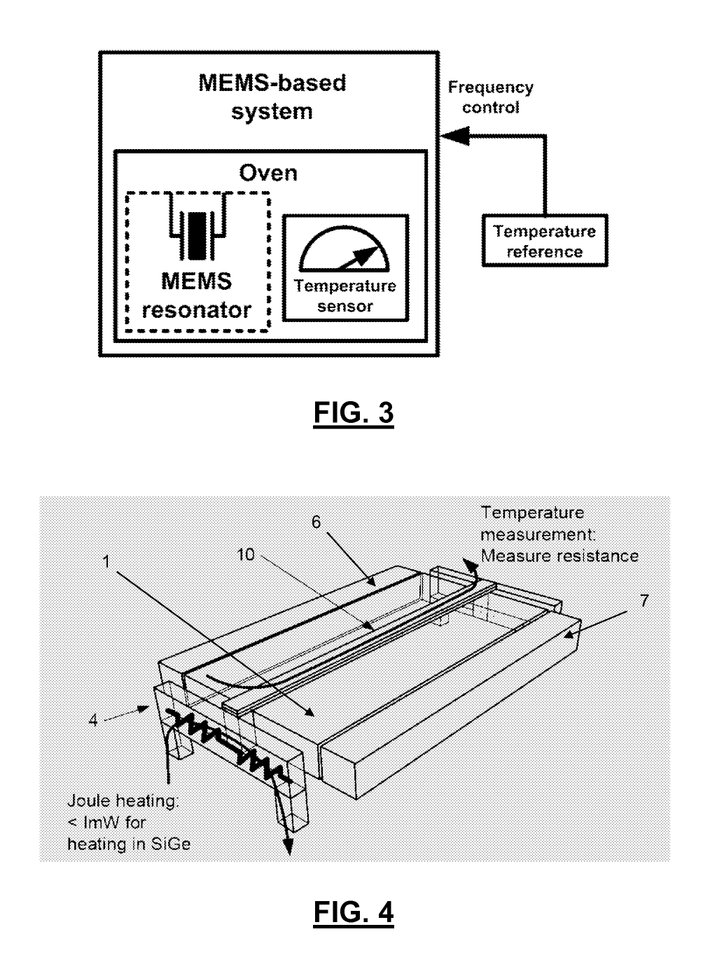

MEM resonator devices exhibit a higher variation of their parameters over temperature in comparison with quartz resonators (see FIG. 2), but nevertheless MEM resonators are gaining interest in view of economic reasons. To solve the temperature variation of the parameters, a stabilization over the temperature is desired. One way of achieving this is through an oven-controlled setup, as shown, for example, in FIG. 3. In such a setup, a MEM device may be placed in a micro-oven, warmed up (to a temperature above ambient, e.g. 70-90° C.), and the temperature of the device may be monitored and kept within a predefined narrow range (e.g., 0.10° C. accurate or less). Hence, the MEMS device is always at substantially the same temperature, and its parameters are substantially fixed, as desired.

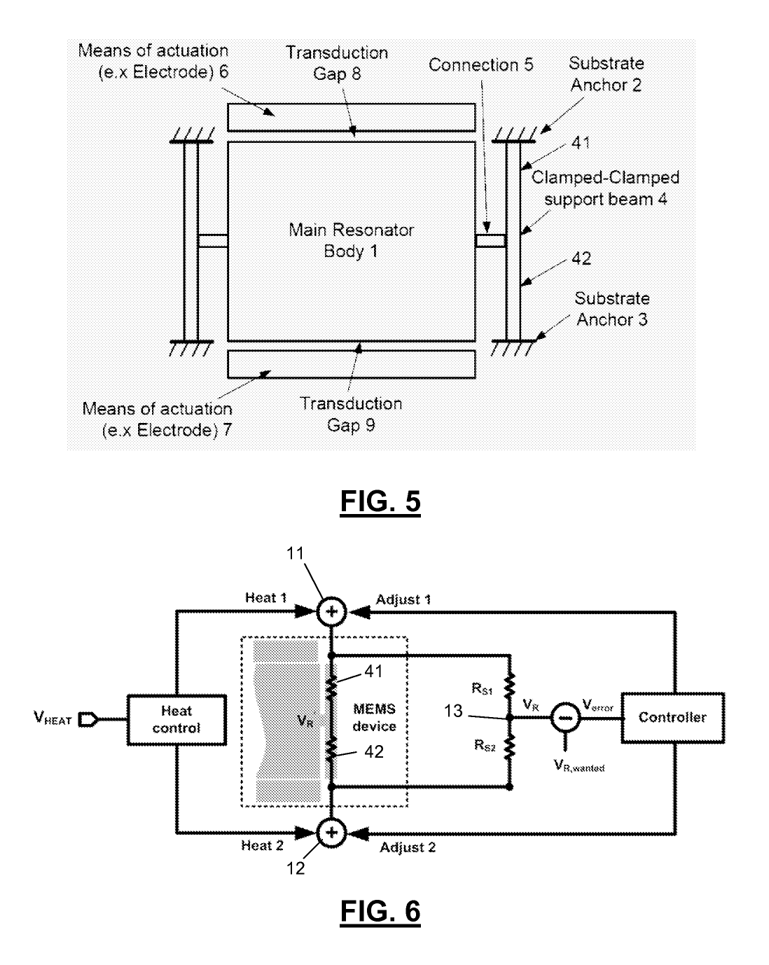

FIG. 5 illustrates and example MEMS resonated device for an ovenized system. As shown, the MEM resonator comprises a main resonator body 1 and at least one means of actuation 6, 7 (e.g., an electrode for applying a bias voltage). The at least one means of actuation 6, 7, may be placed at close proximity, such as at a transduction gap 8, 9, to the main resonator body 1, as shown. The MEM resonator further includes at least one T-shaped support 4 for anchoring the main resonator body 1 to the substrate.

The T-shaped support or T-support comprises a clamped-clamped beam comprising two legs 41, 42 attached by means of anchors 2, 3 to the substrate, and a common connection 5 to the main resonator body 1.

The MEM resonator device or structure is configured to resonate at least in a predetermined mode, such as, for example, a breathing mode. The main resonator body 1 resonates at a resonance frequency (fᵣₑₛ) related to its natural response. The length of the clamped-clamped beams or support is chosen to be in relation to the flexural wavelength (type of wavelength dependent on most important stress component to support) for providing frequency stability and high Q factor. The T-support design utilizing a rigid clamped-clamped support provides electromechanical stability in the direction of actuation. More in particular, the length of each leg 41, 42 of the beam can be chosen as a multiple of half the flexural wavelength plus an offset term so as to be, for example, acoustically long with respect to the flexural wavelength of the beam, thereby enhancing flexibility and minimizing heat losses towards the substrate. In some embodiments, the T-shaped support may not be included; other support types can also be used within the scope of the disclosure, such as, for example, Y-shaped or single mechanical supports or other.

As shown in FIG. 4, the T-shaped supports 4 can be used for heating the MEM resonator main body 1 to the operating temperature. Current is supplied to the T-shaped supports for achieving Joule heating. In order to control the current, the temperature of the main body is measured, for example by means of a resistance 10 on top of the resonator body 1. Using this principle in combination with the acoustically long leg design, power consumption for heating can be reduced to below, for example, 1 mW.

The heating current through the support 4 of the device results in a resistive voltage drop v_{R} over each mechanical support 41, 42. Hence, the bar center voltage changes. As a consequence, the resonator bias voltage may change as a function of heating power. The latter is a function of ambient temperature. The higher the ambient temperature, the lower the required heating power to stabilize the resonator, the lower the current i and the lower the voltage drop v_{R}. The MEMS resonance parameters are partly determined by the bias voltage; in the case of FIGS. 4 and 5, the bias voltage is the voltage difference between the electrostatic actuators 6, 7 and the resonator body 1.

As a consequence, the electrostatic bias voltage may change over temperature. On the other hand, the MEMS resonance frequency is also a function of the resonator bias voltage. Therefore, the frequency is dependent on temperature, not only through heating, but also through the bias change, even when the temperature of the resonator is kept stable.

In order to resolve this unwanted variation of the temperature, i.e., to stabilize the center voltage level of the resonator body 1 at a predetermined level, the voltage level of the resonator body is monitored according to the disclosure by means of a replica circuit and a compensation mechanism, embodiments of which are explained below.

A first embodiment is shown in FIG. 6. Current is driven by means of a sourcing current (or voltage) source 11 and a sinking current (or voltage) source 12 through the mechanical supports 41, 42 for heating the resonator body 1 by Joule heating. The sourcing current source 11 and the sinking current source 12 are initially set to supply currents of equal value, and equal to the target value required for heating the MEM resonator to the desired temperature. Voltage v_{R′} of the resonator body is then sensed by means of a replica circuit, comprising a set of sensing resistors R_{S1} and R_{S2} in parallel over the heating circuit formed by heating resistors 41, 42. These sensing resistors can be of very high value (e.g. at least 10 times or at least 100 times higher than the heating resistances), to not impact the heating mechanism and conduct almost no current. Resistors R_{S1} and R_{S2} are chosen to replicate the resistance ratio of the heating resistors 41, 42, so that the centre 13 between the resistors provides an emulated copy v_{R} of the real internal voltage v_{R′}. The replica voltage v_{R} at the centre 13 between the sensing resistors R_{S1} and R_{S2} is compared with a predetermined voltage v_{R,wanted}. The resulting error signal vₑᵣᵣₒᵣ is fed into a controller for adjusting the current driven by either the sourcing current (or voltage) source 11 or the sinking current (or voltage) source 12, such that the replica voltage v_{R}, and thus the real internal voltage v_{R′} are adjusted towards the predetermined voltage v_{R,wanted}. The feedback loop runs continually, adjusting automatically when the required heater power is changed. The bias voltage of the MEM resonator can hence be kept stable.

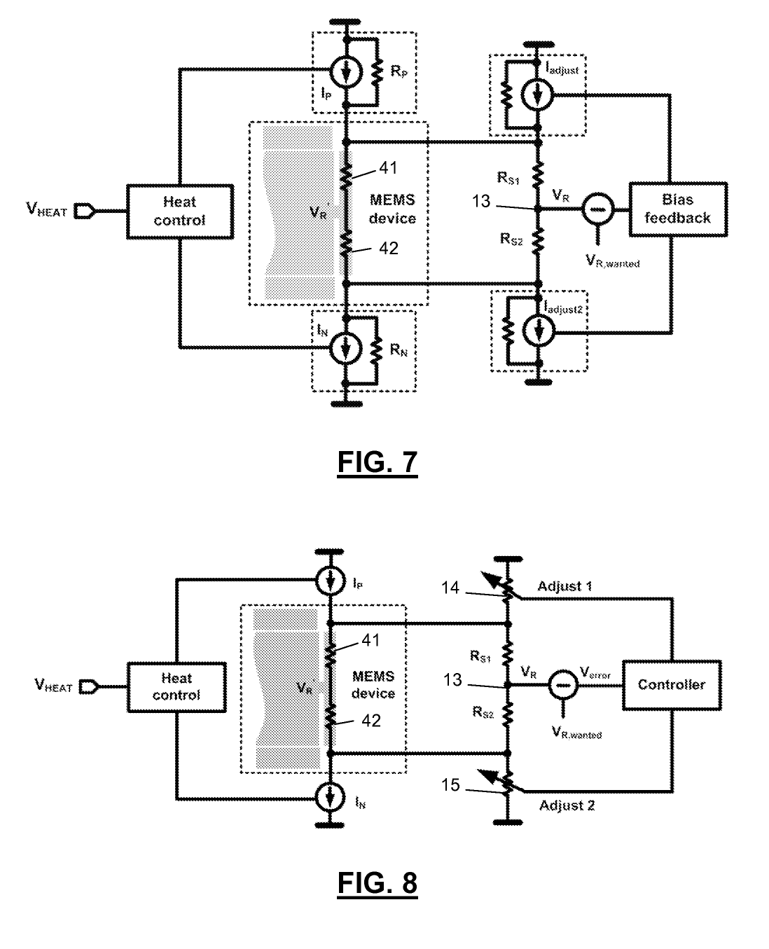

A second embodiment of the disclosure is depicted in FIG. 7. The main current for driving the heating resistances 41, 42 is supplied by means of a positive and negative current source I_{P} and I_{N}. In parallel, a positive adjustment current source I_{ADJUST} and a negative adjustment current source I_{ADJUST2} are provided, controlled by the controller of the bias compensation circuit. The excess current will flow in the output impedance of the current sources (e.g. R_{P} or R_{N}). The bias compensation circuit is otherwise the same as the one of FIG. 6.

A third embodiment is depicted in FIG. 8. Here, the adjustment currents are generated by means of tunable resistors, controlled by the controller of the bias compensation circuit. The bias compensation circuit is otherwise the same as the one of FIG. 6.

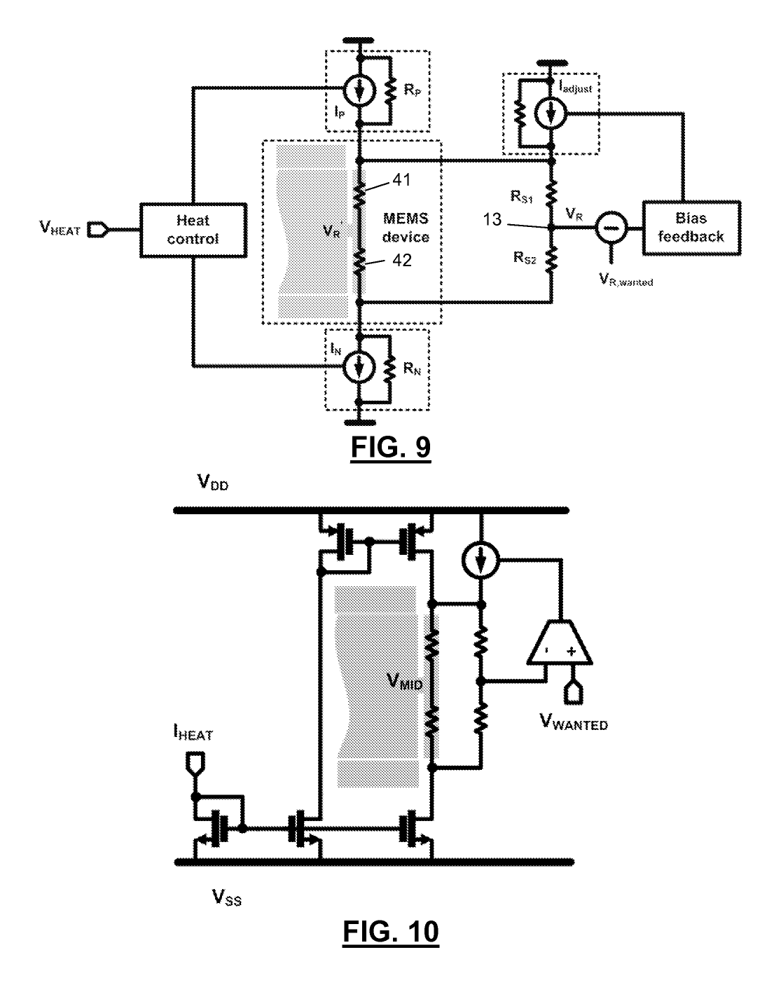

A fourth embodiment is depicted in FIG. 9. Here, there is only the positive adjustment current source, controlled by the controller of the bias compensation circuit.

FIG. 10 shows a practical implementation of the embodiment of FIG. 9. A current input I_{HEAT} sets the wanted heating current by means of a current mirror to a sourcing current source (PMOS, top) and sinking current source (NMOS, bottom), pushing the current through the mechanical support of the resonator (100s of Ohms), producing a center voltage V_{MID}. Two very large (100s of kOhms) sense resistors (external of the MEMS resonator) copy the voltage V_{MID}. A feedback loop drives V_{MID} to be equal to V_{WANTED}, regardless of the wanted heater power set by I_{HEAT}, thanks to a feedback current source.

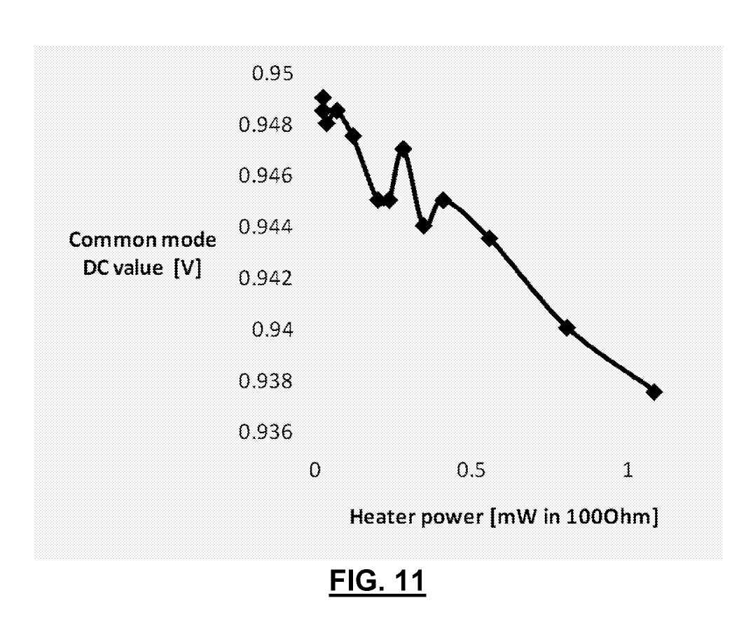

A measurement example is given in FIG. 11, showing that v_{R} (referred to as ‘Common mode DC value’), stays stable up to ˜10 mV over the whole targeted heater power range of 0-1 mW.

In FIGS. 6-10, the controller of the temperature control circuit and the controller of the bias compensation circuit are shown as separate controllers. These can however also be combined into a single controller. The controller(s) can be a combination of analog components and/or a digital controller.

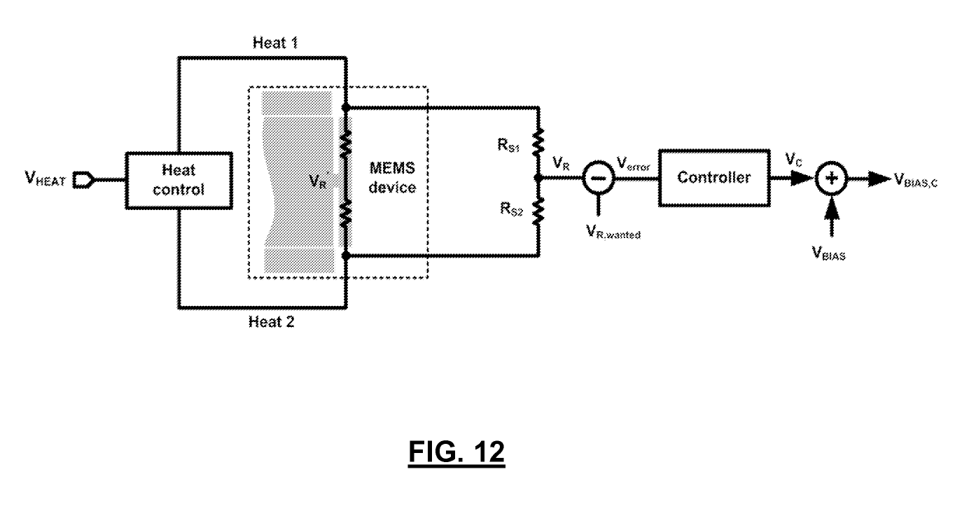

In alternative embodiments (see FIG. 12), one could increase (or decrease) the electrostatic bias voltage (on the electrodes 6, 7) with the same amount as the voltage drop v_{R}, in an open-loop configuration, to counteract the bias voltage variation. This is however more difficult to achieve, since typically the electrostatic actuator voltage is a high voltage (e.g. 50V, high with respect to solid-state technologies)—though not impossible.

### CONCLUSION

The above detailed description describes various features and functions of the disclosed systems, devices, and methods with reference to the accompanying figures. While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A micro-electromechanical (MEM) resonator comprising:
a resonator body suspended above a substrate by means of at least a first and a second mechanical support forming a first and a second heating resistance, respectively, configured to heat the resonator body through Joules heating;
biasing means configured to apply a bias voltage to the resonator body to enable vibration at a predetermined operating frequency;
a temperature control system configured to control the temperature of the micro-electromechanical resonator; and
an internal voltage monitoring system configured to monitor a voltage level of the resonator body.

2. The MEM resonator of claim 1, wherein the temperature control system comprises:
current driving means configured to drive an electrical current through the first and second heating resistances; and
control means configured to control the current driving means.

3. The MEM resonator of claim 2, wherein the internal voltage monitoring system comprises:
a replica circuit comprising a third and a fourth resistance in parallel over the first and second heating resistances and replicating the resistance ratio of the first and second heating resistances, so that an intermediate connection between the third and fourth resistances replicates the voltage level of the resonator body; and
a compensation means connected to the intermediate connection and configured to compensate for deviations of the replicated voltage level from a predetermined voltage level.

4. The MEM resonator of claim 3, wherein the compensation means is configured to adjust the electrical current such that the replicated voltage level is adjusted towards the predetermined voltage level.

5. The MEM resonator of claim 3, wherein the compensation means comprises:
a comparator of which one input node is connected to the intermediate connection and another input node is connected to a means for supplying the predetermined voltage level;
an additional current driving means parallel over the current driving means of the temperature control system; and
an additional control means connected to the comparator and the additional current driving means and configured to control the additional current driving means based on the output of the comparator.

6. The MEM resonator of claim 3, wherein the compensation means comprises:
a difference amplifier of which one input node is connected to the intermediate connection and another input node is connected to a means for supplying the predetermined voltage level;
an additional current driving means parallel over the current driving means of the temperature control system; and
an additional control means connected to the difference amplifier and the additional current driving means and provided for controlling the additional current driving means based on the output of the difference amplifier.

7. The MEM resonator of claim 3, wherein the compensation means comprises a feedback of the replicated voltage level to the control means of the temperature control system.

8. The MEM resonator of claim 3, wherein the current driving means comprises a sourcing current source connected to the first heating resistance and a sinking current source connected to the second heating resistance.

9. The MEM resonator of claim 8, wherein the compensation means comprises at least one of an additional sourcing current source parallel over the sourcing current source and an additional sinking current source parallel over the sinking current source.

10. The MEM resonator of claim 8, wherein the compensation means comprises at least one of a first variable resistance parallel over the sourcing current source and a second variable resistance parallel over the sinking current source.

11. The MEM resonator of claim 3, wherein the compensation means are configured to adjust the bias voltage by an amount that is substantially equal to the deviation of the replicated voltage level from the predetermined voltage level.

12. The MEM resonator of claim 3, wherein the third and fourth resistances have higher resistance values than the first and second resistances.

13. The MEM resonator of claim 2, wherein the first and second heating resistances have substantially the same resistance values.

14. The MEM resonator of claim 1, wherein the first and second mechanical supports are part of a clamped-clamped beam and the resonator body is connected to the first and second mechanical supports by means of a connection part.

15. A method comprising:
providing a micro-electromechanical resonator in an ovenized system, the resonator comprising a resonator body suspended above a substrate by means of at least a first and a second mechanical support forming a first and a second heating resistance, respectively, for heating the resonator body through Joules heating;
applying a bias voltage to the resonator body to enable vibration at a predetermined operating frequency;
controlling the temperature of the micro-electromechanical resonator by means of a temperature control system in which a current driving means drives an electrical current through the first and second heating resistances, and a control means controls the current driving means; and
using an internal voltage monitoring system to monitor the voltage level of the resonator body, wherein monitoring the voltage level comprises:
a) using a replica circuit to replicate the voltage level of the resonator body and replicate the resistance ratio of the first and second heating resistances, wherein the replica circuit comprises a third and a fourth resistance in parallel over the first and second heating resistances such that an intermediate connection between the third and fourth resistances is at a replicated voltage level; and
b) compensating for deviations of the replicated voltage level from a predetermined voltage level.

16. The method of claim 15, wherein compensating for the deviations comprises adjusting the electrical current such that the replicated voltage level is adjusted towards the predetermined voltage level.

17. The method of claim 15, wherein compensating for the deviations comprises adjusting the bias voltage by an amount that is substantially equal to the deviation of the replicated voltage level from the predetermined voltage level.

18. An electronic device comprising:
an ovenized system comprising a micro-electromechanical (MEM) resonator, the MEM resonator comprising:
a resonator body suspended above a substrate by means of at least a first and a second mechanical support forming a first and a second heating resistance, respectively, configured to heat the resonator body through Joules heating;
biasing means configured to apply a bias voltage to the resonator body to enable vibration at a predetermined operating frequency;
a temperature control system configured to control the temperature of the micro-electromechanical resonator; and
an internal voltage monitoring system configured to monitor a voltage level of the resonator body.

19. The electronic device of claim 18, wherein the temperature control system comprises:
current driving means configured to drive an electrical current through the first and second heating resistances; and
control means configured to control the current driving means.

20. The electronic device of claim 19, wherein the internal voltage monitoring system comprises:
a replica circuit comprising a third and a fourth resistance in parallel over the first and second heating resistances and replicating the resistance ratio of the first and second heating resistances, so that an intermediate connection between the third and fourth resistances replicates the voltage level of the resonator body; and
a compensation means connected to the intermediate connection and configured to compensate for deviations of the replicated voltage level from a predetermined voltage level.
